(19) United States
(12) Patent Application Publication
(10) Pub. No.: US 2026/0113973 A1
(43) Pub. Date: Apr. 23, 2026

(54) SINGLE FINFET DEVICE BACKSIDE SOURCE/DRAIN CONTACT FORMATION

(71) Applicant: International Business Machines Corporation, Armonk, NY (US)

(72) Inventors: Erik Milosevic, Schenectady, NY (US); Tao Li, Slingerlands, NY (US); Ruilong Xie, Niskayuna, NY (US); John Christopher Arnold, North Chatham, NY (US)

(21) Appl. No.: 18/921,966

(22) Filed: Oct. 21, 2024

(51) Int. Cl. H01L 29/417; H01L 29/78

(52) U.S. Cl. CPC H10D 30/6219; H10D 30/62

(57) ABSTRACT

According to an embodiment of the present invention, a semiconductor device includes an underlying substrate layer. A backside interlayer dielectric (BILD) layer in direct contact with a backside of the underlying substrate layer. A width of the BILD is greater than a width of the underlying substrate layer. A backside source/drain contact formed through the BILD layer. A width of the backside source/drain contact is identical to the width of the BILD layer.

### BACKGROUND

The present invention relates generally to the field of microelectronics, and more particularly to a semiconductor device structure, and a method for forming a semiconductor device.

A nanosheet (NS) is the lead device architecture in continuing CMOS scaling. However, nanosheet technology has shown issues when scaling down such that as the devices become smaller and closer together, they are interfering with each other. Furthermore, as the devices become smaller and closer together, forming the connections to a backside power network is becoming more difficult.

### SUMMARY

According to an embodiment of the present invention, a semiconductor device includes an underlying substrate layer. A backside interlayer dielectric (BILD) layer in direct contact with a backside of the underlying substrate layer. A width of the BILD is greater than a width of the underlying substrate layer. A backside source/drain contact formed through the BILD layer. A width of the backside source/drain contact is identical to the width of the BILD layer.

According to an embodiment of the present invention, a semiconductor device includes an underlying substrate layer. A backside interlayer dielectric (BILD) layer in direct contact with a backside of the underlying substrate layer. A width of the BILD is greater than a width of the underlying substrate layer. A backside source/drain contact formed through the BILD layer. A width of the backside source/drain contact is identical to the width of the BILD layer. A source/drain placeholder in direct contact with a frontside of the BILD layer. A width of the source/drain placeholder is identical to the width of the BILD layer. A first source/drain in direct contact with a frontside surface of the placeholder.

According to an embodiment of the present invention, a semiconductor device includes an underlying substrate layer. A backside interlayer dielectric (BILD) layer in direct contact with a backside of the underlying substrate layer. A width of the BILD is greater than a width of the underlying substrate layer. A backside source/drain contact formed through the BILD layer. A width of the backside source/drain contact is identical to the width of the BILD layer. A source/drain placeholder in direct contact with a frontside of the BILD layer. A width of the source/drain placeholder is identical to the width of the BILD layer. A first source/drain in direct contact with a frontside surface of the placeholder.

### BRIEF DESCRIPTION OF THE SEVERAL VIEWS OF THE DRAWINGS

These and other objects, features and advantages of the present invention will become apparent from the following detailed description of illustrative embodiments thereof, which is to be read in connection with the accompanying drawings. The various features of the drawings are not to scale as the illustrations are for clarity in facilitating one skilled in the art in understanding the invention in conjunction with the detailed description. In the drawings:

FIG. 1 illustrates a top-down view of a plurality of nanodevices, in accordance with the embodiment of the present invention.

FIG. 2 illustrates cross section Y₁ of the plurality of nanodevices after mandrel patterning, according to the embodiment of the present invention.

FIG. 3 illustrates cross section Y₁ of the plurality of nanodevices after spacer deposition and recessing, according to the embodiment of the present invention.

FIG. 4 illustrates cross section Y₁ of the plurality of nanodevices after mandrel pull and fin reactive ion etching (RIE), according to the embodiment of the present invention.

FIG. 5 illustrates cross section Y₁ of the plurality of nanodevices after spacer deposition and breakthrough, according to the embodiment of the present invention.

FIG. 6 illustrates cross section Y₁ of the plurality of nanodevices after fin shallow trench isolation (STI) etching, according to the embodiment of the present invention.

FIG. 7 illustrates cross section Y₁ of the plurality of nanodevices after selective spacer removal, a first chemical-mechanical planarization (CMP), STI formation, and hard mask removal, according to the embodiment of the present invention.

FIGS. 8 and 9 illustrate cross sections Y₁ and Y₂ of the plurality of nanodevices after dummy gate patterning, gate spacer formation, FIN recess, source/drain (S/D) region recess placeholder formation, and S/D formation, according to the embodiment of the present invention.

FIGS. 10 and 11 illustrate cross sections Y₁ and Y₂ of the plurality of nanodevices after interlayer dielectric (ILD) fill, POC, dummy gate removal, high-k metal gate (HKMG) formation, middle-of-line (MOL) contact formation, back-end-of-line (BEOL) formation, and carrier wafer bonding, according to the embodiment of the present invention.

FIGS. 12 and 13 illustrate cross sections Y₁ and Y₂ of the plurality of nanodevices after wafer flip, backside substrate grinding and a second CMP according to the embodiment of the present invention.

FIGS. 14 and 15 illustrate cross sections Y₁ and Y₂ of the plurality of nanodevices after etch stop layer removal, remaining substrate removal, buried interlayer dielectric (BILD) fill, and a third CMP, according to the embodiment of the present invention.

FIGS. 16 and 17 illustrate cross sections Y₁ and Y₂ of the plurality of nanodevices after backside contact patterning, placeholder removal, backside contact metallization, and backside interconnect formation, according to the embodiment of the present invention.

### DETAILED DESCRIPTION

Detailed embodiments of the claimed structures and methods are disclosed herein; however, it can be understood that the disclosed embodiments are merely illustrative of the claimed structures and methods that may be embodied in various forms. This invention may, however, be embodied in many different forms and should not be construed as limited to the exemplary embodiments set forth herein. In the description, details of well-known features and techniques may be omitted to avoid unnecessarily obscuring the presented embodiments.

It is to be understood that the singular forms “a,” “an,” and “the” include plural referents unless the context clearly dictates otherwise. Thus, for example, reference to “a component surface” includes reference to one or more of such surfaces unless the context clearly dictates otherwise.

References in the specification to “one embodiment,” “an embodiment,” “an example embodiment,” etc., indicate that the embodiment described may include a particular feature, structure, or characteristic, but every embodiment may not include the particular feature, structure, or characteristic. Moreover, such phrases are not necessarily referring to the same embodiment. Further, when a particular feature, structure, or characteristic is described in connection with an embodiment, it is submitted that it is within the knowledge of one of ordinary skill in the art to affect such feature, structure, or characteristic in connection with other embodiments whether or not explicitly described.

For purpose of the description hereinafter, the terms “upper,” “lower,” “right,” “left,” “vertical,” “horizontal,” “top,” “bottom,” and derivatives thereof shall relate to the disclosed structures and methods, as orientated in the drawing figures. The terms “overlying,” “atop,” “on top,” “formed on,” or “formed atop” mean that a first element, such as a first structure, is present on a second element, such as a second structure, where intervening elements, such as an interface structure may be present between the first element and the second element. The term “direct contact” means that a first element, such as a first structure, and a second element, such as a second structure, are connected without any intermediary conducting, insulating, or semiconductor layer at the interface of the two elements.

In the interest of not obscuring the presentation of embodiments of the present invention, in the following detailed description, some processing steps or operations that are known in the art may have been combined together for presentation and for illustrative purposes and in some instance may have not been described in detail. In other instances, some processing steps or operations that are known in the art may not be described at all. It should be understood that the following description is rather focused on the distinctive features or elements of various embodiments of the present invention.

Various embodiments of the present invention are described herein with reference to the related drawings. Alternative embodiments can be devised without departing from the scope of this invention. It is noted that various connections and positional relationships (e.g., over, below, adjacent, etc.) are set forth between elements in the following description and in the drawings. These connections and/or positional relationships, unless specified otherwise, can be direct or indirect, and the present invention is not intended to be limiting in this respect. Accordingly, a coupling of entities can refer to either a direct or indirect coupling, and a positional relationship between entities can be a direct or indirect positional relationship. As an example of an indirect positional relationship, references in the present description to forming layer “A” over layer “B” includes situations in which one or more intermediate layers (e.g., layer “C”) is between layer “A” and layer “B” as long as the relevant characteristics and functionalities of layer “A” and layer “B” are not substantially changed by the intermediate layer(s).

The following definitions and abbreviations are to be used for the interpretation of the claims and the specification. As used herein, the terms “comprises,” “comprising,” “includes,” “including,” “has,” “having,” “contains,” or “containing” or any other variation thereof, are intended to cover a non-exclusive inclusion. For example, a composition, a mixture, process, method, article, or apparatus that comprises a list of elements is not necessarily limited to only those elements but can include other element not expressly listed or inherent to such composition, mixture, process, method, article, or apparatus.

Additionally, the term “exemplary” is used herein to mean “serving as an example, instance or illustration.” Any embodiment or design described herein as “exemplary” is not necessarily to be construed as preferred or advantageous over other embodiment or designs. The terms “at least one” and “one or more” can be understood to include any integer number greater than or equal to one, i.e., one, two, three, four, etc. The terms “a plurality” can be understood to include any integer number greater than or equal to two, i.e., two, three, four, five, etc. The term “connection” can include both an indirect “connection” and a direct “connection.”

As used herein, the term “about” modifying the quantity of an ingredient, component, or reactant of the invention employed refers to variation in the numerical quantity that can occur, for example, through typical measuring and liquid handling procedures used for making concentrations or solutions. Furthermore, variation can occur from inadvertent error in measuring procedures, differences in manufacture, source, or purity of the ingredients employed to make the compositions or carry out the methods, and the like. The terms “about” or “substantially” are intended to include the degree of error associated with measurement of the particular quantity based upon the equipment available at the time of the filing of the application. For example, about can include a range of ±8%, or 5%, or 2% of a given value. In another aspect, the term “about” means within 5% of the reported numerical value. In another aspect, the term “about” means within 10, 9, 8, 7, 6, 5, 4, 3, 2, or 1% of the reported numerical value.

Various processes which are used to form a micro-chip that will be packaged into an integrated circuit (IC) fall in four general categories, namely, film deposition, removal/etching, semiconductor doping and patterning/lithography. Deposition is any process that grows, coats, or otherwise transfers a material onto the wafer. Available technologies include physical vapor deposition (PVD), chemical vapor deposition (CVD), electrochemical deposition (ECD), molecular beam epitaxy (MBE), and more recently, atomic layer deposition (ALD) among others. Removal/etching is any process that removes material from the wafer. Examples include etching process (either wet or dry), reactive ion etching (RIE), and chemical-mechanical planarization (CMP), and the like. Semiconductor doping is the modification of electrical properties by doping, for example, transistor sources and drains, generally by diffusion and/or by ion implantation. These doping processes are followed by furnace annealing or by rapid thermal annealing (RTA). Annealing serves to activate the implant dopants. Films of both conductors (e.g., aluminum, copper, etc.) and insulators (e.g., various forms of silicon dioxide, silicon nitride, etc.) are used to connect and isolate electrical components. Selective doping of various regions of the semiconductor substrate allows the conductivity of the substrate to be changed with the application of voltage.

Reference will now be made in detail to the embodiments of the present invention, examples of which are illustrated in the accompanying drawings, where like reference numerals refer to like elements throughout.

When forming single fin FinFET devices, a placeholder is formed under the single fin. However, forming a small placeholder under the single fin of a single fin FinFET device is a concern for reliability of a direct backside contact scheme in a backside power delivery network (BSPDN). The present invention is directed towards forming a single fin FinFET device with a larger critical dimension placeholder under the device to provide better process margin and bottom source/drain contact area (BSCA) formation for a double bottom contact (DBC) scheme. The present invention does not require that all advantages need to be incorporated into every embodiment of the invention.

The present invention is directed to forming a single FinFET device with an active fin critical dimension smaller than an STI critical dimension. The single FinFET device is formed through a multistage processing, where the first stage forms a modified nanosheet stack and performs mandrel patterning. The second stage forms a first gate spacer. The third stage forms fins through reactive ion etching (RIE). The fourth stage forms a second gate spacer. The fifth stage forms recesses through a fin STI etch. The sixth stage forms an STI region and performs a first CMP. The seventh stage forms S/D region recess placeholders and an S/D region. The eighth stage forms an ILD, an HKMG, an MOL contact, and a BEOL. The ninth stage performs backside substrate removal and a second CMP. The tenth stage removes an etch stop layer and remaining substrate and performs a BILD fill and a third CMP. The eleventh stage performs backside contact patterning, placeholder removal, backside contact metallization, and backside interconnect formation.

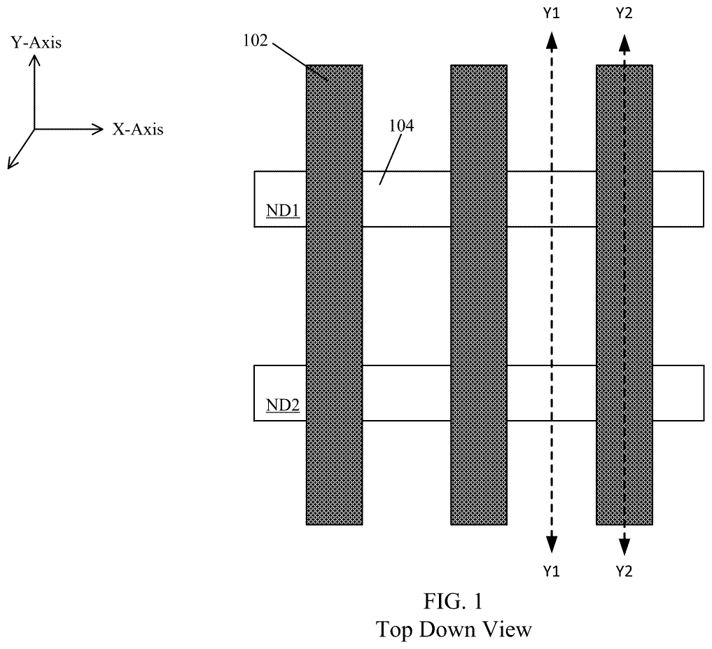

FIG. 1 illustrates a top-down view of a plurality of nanodevices ND1, ND2, in accordance with the embodiment of the present invention. The adjacent and parallel devices along an x-axis include a first nanodevice ND1 including a plurality of first transistors and a second nanodevice ND2 including a plurality of second transistors. The adjacent and parallel devices along a y-axis include gates within a gate region 102. Cross-section Y₁ is a cross section parallel to the gates in the source/drain region 104 across the plurality of nanodevices ND1, ND2. Cross-section Y₂ is a cross section parallel to the gates in the gate region 102 across the plurality of nanodevices ND1, ND2. It may be appreciated that the embodiment of the present invention is not limited to nanodevices ND1, ND2 and that other devices including, but not limited to, nanosheet transistors, FinFET, nanowire, and a planar device may also be used.

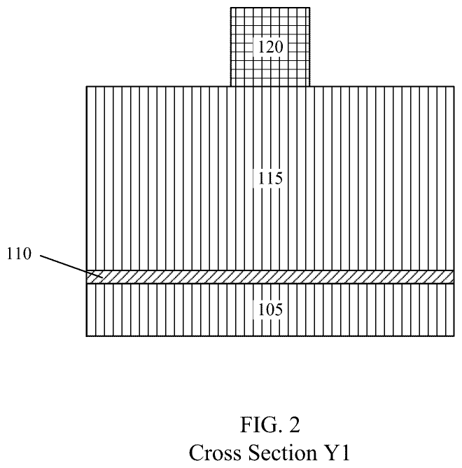

FIG. 2 illustrates cross section Y₁ of the plurality of nanodevices ND1, ND2 after mandrel 120 patterning, according to the embodiment of the present invention. The modified nanosheet stack may include various layers of semiconductor materials, such as a first substrate layer 105, an etch stop layer 110, and an underlying substrate layer 115. The first substrate layer 105, the etch stop layer 110, and the underlying substrate layer 115 can be, for example, a material including, but not necessarily limited to, silicon (Si), silicon germanium (SiGe), Si:C (carbon doped silicon), carbon doped silicon germanium (SiGe:C), III-V, II-V compound semiconductor or another like semiconductor. In addition, multiple layers of the semiconductor materials can be used as the semiconductor material of the first substrate layer 105 and the underlying substrate layer 115. In the embodiment, the first substrate layer 105 and the underlying substrate layer 115 include both semiconductor materials and dielectric materials. The first substrate layer 105 and the underlying substrate layer 115 may also comprise an organic semiconductor or a layered semiconductor such as, for example, Si/SiGe, a silicon-on-insulator or a SiGe-on-insulator. A portion or the entire first substrate layer 105 and a portion or the entire underlying substrate layer 115 may also be comprised of an amorphous, polycrystalline, or monocrystalline. The first substrate layer 105 and the underlying substrate layer 115 may be doped, undoped or contain doped regions and undoped regions therein. For example, the first substrate layer 105 and the underlying substrate layer 115 layer may be comprised of silicon, whereas the etch stop layer 110 may be comprised of silicon nitride (Si₃N₄), silicon carbide (SiC), or silicon carbonitride (SiCN).

A mandrel 120 pattern is formed directly atop the underlying substrate layer 115. The mandrel 120 pattern is formed during mandrel patterning to define a plurality of fins when forming fin-like field effect transistors (FinFETs). The mandrel 120 pattern may be comprised of a dielectric material, such a-Si.

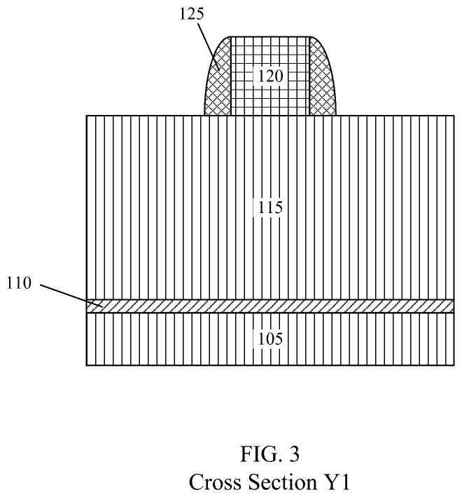

FIG. 3 illustrates cross section Y₁ of the plurality of nanodevices ND1, ND2 after first spacer 125 deposition and recessing, according to the embodiment of the present invention. After formation of mandrel 120 pattern, first spacers 125 are formed on exposed sidewalls of the mandrel 120. The first spacers 125 may be comprised of a dielectric material.

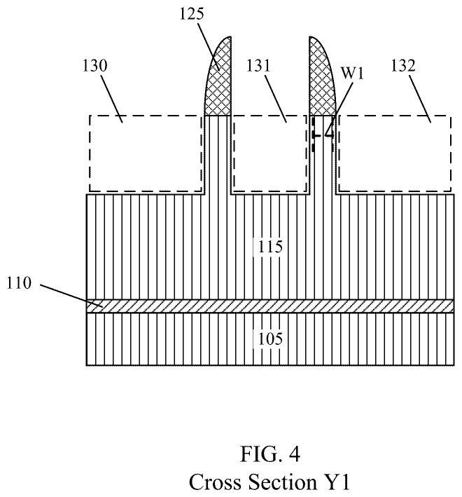

FIG. 4 illustrates cross section Y₁ of the plurality of nanodevices ND1, ND2 after mandrel 120 pull and fin reactive ion etching (RIE), according to the embodiment of the present invention. After formation of the first spacers 125, the mandrel 120 pattern is removed and a portion of the underlying substrate layer 115 is etched, through fin RIE, around the first spacers 125 to form a first plurality of trenches 130-132. The etching leaves the second substrate layer directly beneath the first spacers 125 intact. The underlying substrate layer 115 remaining between the first plurality of trenches 130-132 has a width W1.

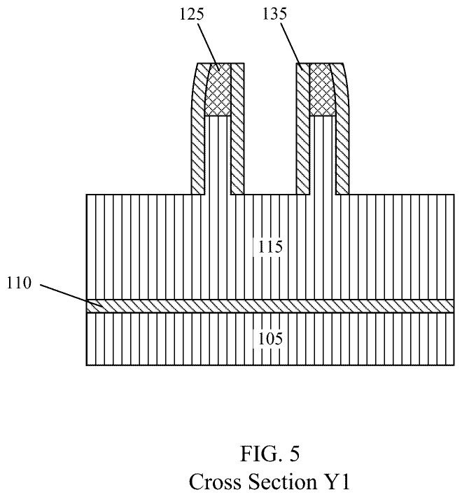

FIG. 5 illustrates cross section Y₁ of the plurality of nanodevices ND1, ND2 after second spacer 135 deposition and breakthrough, according to the embodiment of the present invention. After mandrel 120 pull and fin RIE, second spacers 135 are formed on exposed sidewalls of the first spacers 125 and exposed sidewalls of the underlying substrate layer 115 inside the first plurality of trenches 130-132. Then, a frontside portion of the first spacers 125 and a frontside portion of the second spacers 135 are etched through RIE (not shown).

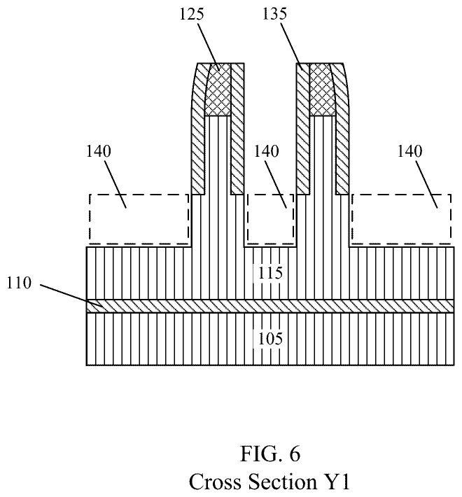

FIG. 6 illustrates cross section Y₁ of the plurality of nanodevices ND1, ND2 after fin shallow trench isolation (STI) etching, according to the embodiment of the present invention. After deposition of second spacers 135, further etching is performed through a second portion of the underlying substrate layer 115 to form a second plurality of trenches 140-142. The etching is performed so that sidewalls exposed by the etching are flush with exposed sidewalls of the second spacers 135.

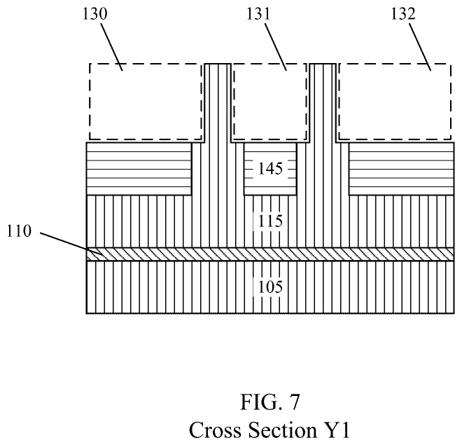

FIG. 7 illustrates cross section Y₁ of the plurality of nanodevices ND1, ND2 after selective removal of the first spacers 125 and the second spacers 135, STI region 145 formation, and hard mask (not shown) removal, according to the embodiment of the present invention. The STI region 145 is formed in the second plurality of trenches 140-142 and a first chemical-mechanical planarization (CMP) is performed. Then, the first spacers 125 and the second spacers 135 are remove through a wet etch process.

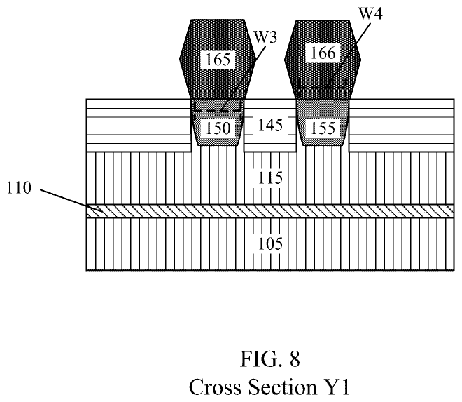

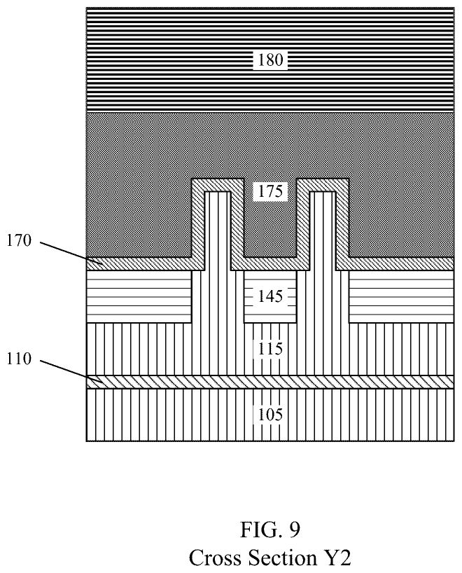

FIGS. 8 and 9 illustrate cross sections Y₁ and Y₂ of the plurality of nanodevices ND1, ND2 after dummy gate 175 patterning, gate spacer 170 formation, FIN recess, source/drain (S/D) placeholder 150, 155 formation, and S/D 165, 166 formation, according to the embodiment of the present invention. In FIG. 8, a third plurality of trenches (not shown) are formed through a portion of the underlying substrate layer 115 between the first plurality of trenches 130-132 and the STI region 145. Then, a first S/D placeholder 150 and a second S/D placeholder 155 are formed in the third plurality of trenches. A first source/drain 165 and a second source/drain 166 are formed directly atop the first S/D placeholder 150 and the second S/D placeholder 155, respectively. Each S/D placeholder 150, 155 has a width W3 and each source/drain 165, 166 has a width W4 that is identical to the width W3 of the S/D placeholders 150, 155. The source/drains 165, 166 can be for example, a n-type epitaxy, or a p-type epitaxy. For n-type epitaxy, an n-type dopant selected from a group of phosphorus (P), arsenic (As) and/or antimony (Sb) can be used. For p-type epitaxy, a p-type dopant selected from a group of boron (B), gallium (Ga), indium (In), and/or thallium (Tl) can be used. Other doping techniques such as ion implantation, gas phase doping, plasma doping, plasma immersion ion implantation, cluster doping, infusion doping, liquid phase doping, solid phase doping, and/or any suitable combination of those techniques can be used. In some embodiments, dopants are activated by thermal annealing such as laser annealing, flash annealing, rapid thermal annealing (RTA) or any suitable combination of those techniques.

In FIG. 9, a gate spacer 170 is deposited and formed directly atop STI region 145 and directly atop the underlying substrate layer 115. Then, a dummy gate 175 is formed directly atop the gate spacer 170 and a hard mark 180 is then formed directly atop the dummy gate 175.

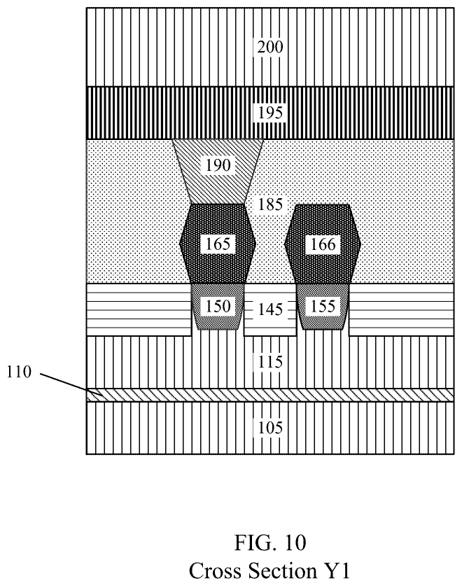

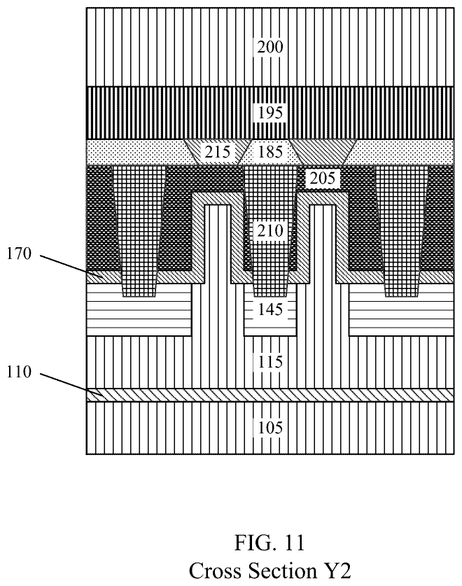

FIGS. 10 and 11 illustrate cross sections Y₁ and Y₂ of the plurality of nanodevices ND1, ND2 after interlayer dielectric (ILD) 185 fill, point-of-contact (POC) liner formation, dummy gate 175 removal, high-k metal gate (HKMG) 205 formation, source/drain contact 190 formation, gate contact 215 formation, back-end-of-line (BEOL) layer 195 formation, and carrier wafer 200 bonding, according to the embodiment of the present invention. In FIG. 10, ILD 185 is formed directly atop the STI region 145, the first S/D region recess placeholder 150, the second S/D region recess placeholder 155, and the source/drains 165, 166. Then, a fourth plurality of trenches (not shown) are formed through the ILD 185 to expose a frontside surface of source/drain 165. The fourth plurality of trenches are then filled with a conductive metal to form a source/drain contact 190 (e.g., including a silicide liner, such as Ni, Ti, NiPt, an adhesion metal liner, such as TiN and conductive metal fill, such as W, Co, or Ru). A back-end-of-line (BEOL) layer 195 is then formed directly atop the ILD 185 and the source/drain contact 190. The BEOL layer 195 may contain multiple metal layers and vias in between. A carrier wafer 200 is then formed directly atop the BEOL layer 195.

In FIG. 11, HKMG 205 is formed directly atop the gate spacer 170. Gate cut dielectric pillars 210 are then formed through the HKMG 205, gate spacer 170, and a portion of the STI region 145. ILD 185 is then formed directly atop the HKMG 205 and gate cut dielectric pillars 210. A fifth plurality of trenches (not shown) are formed through the ILD 185 between the gate cut dielectric pillars 210. The fifth plurality of trenches are then filled with a conductive metal to form the plurality of gate contacts 215. BEOL layer 195 is then formed directly atop the ILD 185 and the source/drain contact 190. A carrier wafer 200 is then formed directly atop the BEOL layer 195.

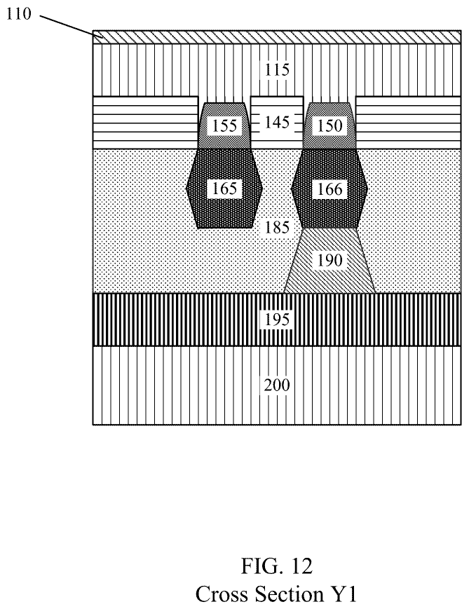

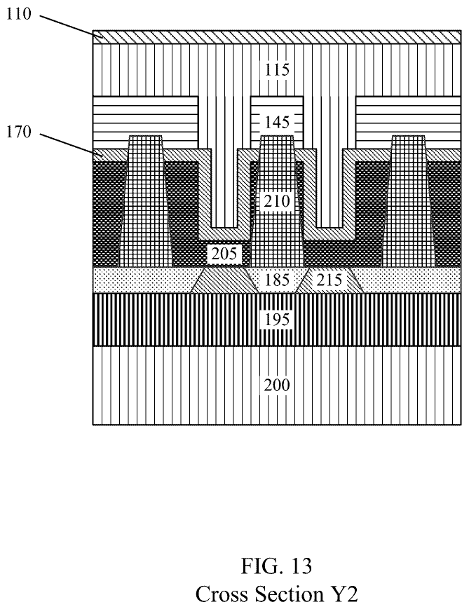

FIGS. 12 and 13 illustrate cross sections Y₁ and Y₂ of the plurality of nanodevices ND1, ND2 after wafer 200 flip, backside substrate grinding and a second CMP according to the embodiment of the present invention. A wafer flip is performed so the carrier wafer 200 becomes a handler wafer. Once flipped, the first substrate layer 105 is removed through backside substrate grinding and CMP, for example, is performed.

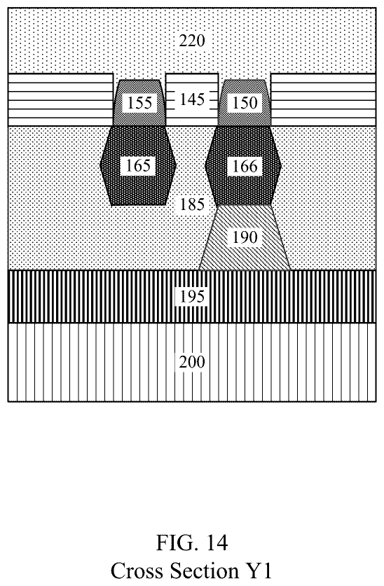

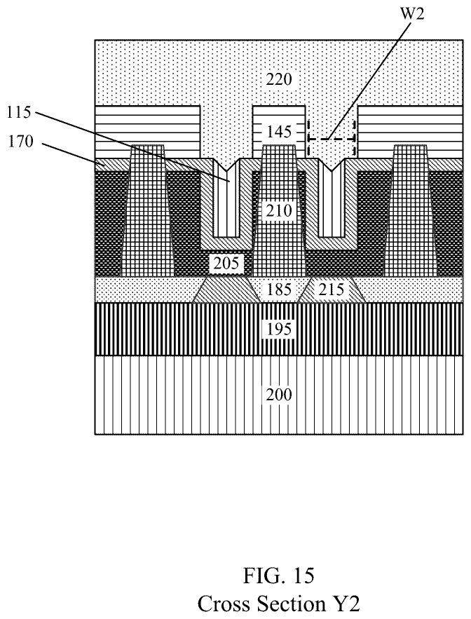

FIGS. 14 and 15 illustrate cross sections Y₁ and Y₂ of the plurality of nanodevices ND1, ND2 after etch stop layer 110 removal, underlying substrate layer 115 removal, buried interlayer dielectric (BILD) 220 fill, and a third CMP, according to the embodiment of the present invention. The etch stop layer 110 is subsequently removed. In FIG. 14, the underlying substrate layer 115 is removed to expose the frontside of the STI region 145 and the source/drains 150, 155. The BILD layer 220 is deposited direction atop the STI region 145 and the source/drains 150, 155. Then, a portion of the BILD layer 220 is selectively removed by, for example, CMP. In FIG. 15, a portion of the underlying substrate layer 115 is removed to expose the frontside of the STI region 145 and the frontside of the gate spacer 170. A sixth plurality of trenches (not shown) (referred to as an indentation in the claims) are formed through a portion of the underlying substrate layer 115. The sixth plurality of trenches are triangular in shape. The BILD layer 220 is deposited directly atop the STI region 145 and the gate spacer 170 and fill the sixth plurality of trenches. The BILD layer 220 has a width W2 and the width W1 of the underlying substrate 115 remaining between the first plurality of trenches 130-132 is greater than the width W2 of the BILD layer 220. Additionally, the width W3 of S/D placeholders 150, 155 is identical to the width W2 of the underlying substrate layer 115 remaining between the second plurality of trenches 140-142 and the width W4 of the source/drains 165, 166. Then, a portion of the BILD layer 220 is selectively removed by, for example, CMP.

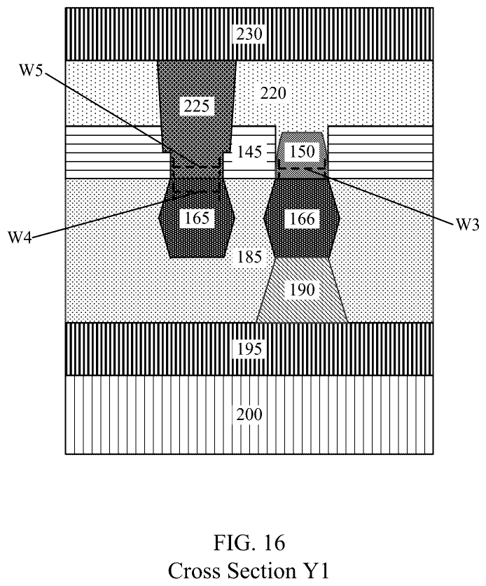

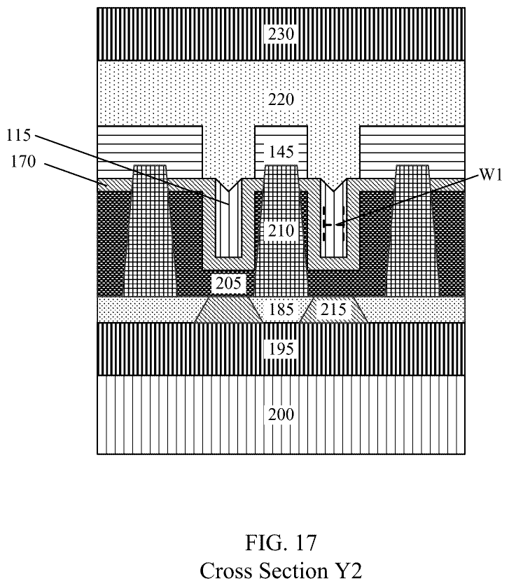

FIGS. 16 and 17 illustrate cross sections Y₁ and Y₂ of the plurality of nanodevices ND1, ND2 after backside source/drain contact 225 patterning, placeholder 155 removal, backside source/drain contact 225 metallization, and backside interconnect 230 formation, according to the embodiment of the present invention. In FIG. 16, a seventh trench (not shown) is formed through the BILD layer 220 and the second S/D placeholder 155, which removes the second S/D placeholder 155 through a selective wets etching process. An eighth trench (not shown), with a width greater than the seventh trench, is formed through the BILD layer 220 and a portion of the STI region 145 and the seventh trench. The seventh trench and the eighth trench are filled with a conductive metal (e.g., including a silicide liner, such as Ni, Ti, NiPt, an adhesion metal liner, such as TiN and conductive metal fill, such as W, Co, or Ru) to form backside source/drain contact 225. The backside source/drain contact 225 is located directly atop the first source/drain 165. A backside interconnect 230 is formed directly atop the BILD layer 220 and the backside source/drain contact 225. The backside interconnect 230 is formed with the same metals, or metal layers, and vias in between as the BEOL layer 195. In FIG. 17, the backside interconnect is formed directly atop the BILD layer 220.

The first backside source/drain contact 225 has two separate horizontal frontside surfaces. A first horizontal frontside surface of the two separate horizontal frontside surfaces is in direct contact with a portion of the STI region 145. A second horizontal frontside surface of the two separate horizontal frontside surfaces is directly atop the first source/drain 165. The second horizontal surface of the backside source/drain contact has a width W5. The width W5 of the backside source/drain contact is identical to the width W2 of the BILD layer 220, the width W3 of the source/drain placeholders 150, 155, and the width W4 of the source/drains 165, 166.

It may be appreciated that FIGS. 1-17 provide only an illustration of one implementation and do not imply any limitations with regard to how different embodiments may be implemented. Many modifications to the depicted environments may be made based on design and implementation requirements. The descriptions of the various embodiments of the present invention have been presented for purposes of illustration, but are not intended to be exhaustive or limited to the embodiments disclosed. Many modifications and variations will be apparent to those of ordinary skill in the art without departing from the scope of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A semiconductor device comprising:
an underlying substrate layer;
a backside interlayer dielectric (BILD) layer in direct contact with a backside of the underlying substrate layer, wherein a width of the BILD layer is greater than a width of the underlying substrate layer; and
a backside source/drain contact extending through the BILD layer, wherein a width of the backside source/drain contact is identical to the width of the BILD layer.

2. The semiconductor device of claim 1, wherein a backside surface of the underlying substrate layer defines an indentation, wherein a portion of the BILD layer fills the indentation.

3. The semiconductor device of claim 1, wherein the backside source/drain contact has two separate horizontal frontside surfaces.

4. The semiconductor device of claim 3, wherein a first horizontal surface of the two separate horizontal surfaces is in direct contact with a portion of an STI region.

5. The semiconductor device of claim 4, further comprising:
a source/drain in direct contact with a frontside surface of the backside source/drain contact.

6. The semiconductor device of claim 5, wherein a second horizontal surface of the two separate horizontal surfaces is in direct contact with the source/drain.

7. The semiconductor device of claim 6, wherein a width of the source/drain is identical to the width of the backside source/drain contact.

8. A semiconductor device comprising:
an underlying substrate layer;
a backside interlayer dielectric (BILD) layer in direct contact with a backside of the underlying substrate layer, wherein a width of the BILD is greater than a width of the underlying substrate layer;
a backside source/drain contact formed through the BILD layer, wherein a width of the backside source/drain contact is identical to the width of the BILD layer; and
a source/drain placeholder in direct contact with a frontside of the BILD layer, wherein a width of the source/drain placeholder is identical to the width of the BILD layer.

9. The semiconductor device of claim 8, wherein a backside surface of the underlying substrate layer defines an indentation, wherein a portion of the BILD layer fills the indentation.

10. The semiconductor device of claim 8, wherein the backside source/drain contact has two separate horizontal frontside surfaces.

11. The semiconductor device of claim 10, wherein a first horizontal surface of the two separate horizontal surfaces is in direct contact with a portion of an STI region.

12. The semiconductor device of claim 11, further comprising:
a source/drain in direct contact with a frontside surface of the backside source/drain contact.

13. The semiconductor device of claim 12, wherein a second horizontal surface of the two separate horizontal surfaces is in direct contact with the source/drain.

14. The semiconductor device of claim 13, wherein a width of the source/drain is identical to the width of the backside source/drain contact.

15. A semiconductor device comprising:
an underlying substrate layer;
a backside interlayer dielectric (BILD) layer in direct contact with a backside of the underlying substrate layer, wherein a width of the BILD is greater than a width of the underlying substrate layer;
a backside source/drain contact formed through the BILD layer, wherein a width of the backside source/drain contact is identical to the width of the BILD layer;
a source/drain placeholder in direct contact with a frontside of the BILD layer, wherein a width of the source/drain placeholder is identical to the width of the BILD layer; and
a first source/drain in direct contact with a frontside surface of the placeholder.

16. The semiconductor device of claim 15, wherein a backside surface of the underlying substrate layer defines an indentation, wherein a portion of the BILD layer fills the indentation.

17. The semiconductor device of claim 15, wherein the backside source/drain contact has two separate horizontal frontside surfaces.

18. The semiconductor device of claim 17, wherein a first horizontal surface of the two separate horizontal surfaces is in direct contact with a portion of an STI region.

19. The semiconductor device of claim 18, further comprising:
a source/drain in direct contact with a frontside surface of the backside source/drain contact.

20. The semiconductor device of claim 19, wherein a second horizontal surface of the two separate horizontal surfaces is in direct contact with the source/drain.
